(19) United States
(12) Patent Application Publication
(10) Pub. No.: US 2007/0051993 A1
(43) Pub. Date: Mar. 8, 2007

(54) Method of forming thin film transistor and poly silicon layer of low-temperature poly silicon thin film transistor

(76) Inventors: Ming-Che Ho, Bade City (TW); Yun-Pei Yang, Lugang Township (TW); Po-Chih Liu, Lujhou City (TW); Chia-Chien Lu, Taipei City (TW)

Correspondence Address: J C PATENTS, INC., 4 VENTURE, SUITE 250, IRVINE, CA, 92618, US

(21) Appl. No.: 11/222,923

(22) Filed: Sep. 8, 2005

(51) Int. Cl. H01L 29/94; G12B 21/02

(52) U.S. Cl. 257/296; 438/496; 257/E29.151

(57) ABSTRACT

A method of forming a thin film transistor is provided. First, an amorphous silicon layer is formed on a substrate. Next, a first gate insulating layer is formed on the amorphous silicon layer. Then, an annealing process is performed so that the amorphous silicon layer is melted and re-crystallized to form a poly silicon layer. Next, the first insulating layer and the poly silicon layer are patterned to form an island. Then, a gate electrode is formed on the island. Finally, a source region and a drain region are formed inside the poly silicon layer of the island. After the annealing process is performed, the boundary between the poly silicon layer and the gate insulating layer becomes denser, so that the current leakage of the thin film transistor can be reduced.

### BACKGROUND OF THE INVENTION

1. Field of the Invention

The present invention generally relates to a method of forming a poly silicon layer of a thin film transistor. More particularly, the present invention relates to a method of forming a thin film transistor and a poly silicon layer of a low-temperature poly silicon thin film transistor.

2. Description of Related Art

The thin film transistor can be divided into the amorphous silicon thin film transistor (a-Si) and the poly silicon thin film transistor according to the material of the channel layer. Compared with the amorphous silicon thin film transistor, the poly silicon thin film transistor has the advantages of low power consumption and higher electron mobility. Therefore, the poly silicon thin film transistor attracts more attention in the industry.

FIGS. 1A to 1D are cross sectional views showing a conventional fabrication process of a low temperature poly silicon (LTPS) thin film transistor. First, please refer to FIG. 1A, a substrate 100 is provided and an amorphous silicon layer 102 is formed on the substrate 100. After that, a laser annealing process or a high temperature annealing process is performed such that the amorphous silicon layer 102 is melted and re-crystallized to form a poly silicon layer 102a shown in FIG. 1B. Next, a gate insulating layer 104 and a gate electrode 106 are formed on the poly silicon layer 102a subsequently. Thereafter, please refer to FIG. 1C, a doping process is performed on the poly silicon layer 102a by using the gate electrode 106 as a mask, to form a source region 108 and a drain region 110 in the poly silicon layer 102a corresponding in location to one side and the other side of the gate electrode 106 respectively as shown in FIG. 1D. The LTPS thin film transistor 120 is therefore completed by following the above-mentioned steps where the poly silicon layer 102a disposed below the gate electrode 106 is a channel layer 112.

In the above-mentioned fabrication process of LTPS thin film transistor, the steps of forming the poly silicon layer and the gate insulating layer are the key points for determining the characteristics of the thin film transistor. More specifically, the trap density of the boundary between the poly silicon layer and the gate insulating layer will affect the current leakage occurred in the thin film transistor during operation. Therefore, the solution of how to improve the trap density of the boundary between the poly silicon layer and the gate insulating layer to lower the current leakage of the poly silicon thin film transistor is highly desired in the technology.

### SUMMARY OF THE INVENTION

A main purpose of the present invention is to provide a method of forming a thin film transistor which utilizes an annealing process to make a boundary between a poly silicon layer and a gate insulating layer of a thin film transistor become denser, to reduce the current leakage of the thin film transistor during operation.

A second purpose of the present invention is to provide a method of forming a poly silicon layer of a LTPS thin film transistor. The method is applied to the fabrication process of a top gate LTPS thin film transistor, to lower the current leakage of the thin film transistor formed by this method.

As embodied and broadly described herein, the present invention provides a method of forming a thin film transistor comprising the following steps. First, an amorphous silicon layer is formed on a substrate. Then, a first gate insulating layer is formed on the amorphous silicon layer. Next, an annealing process is performed such that the amorphous silicon layer is melted and re-crystallized to form a poly silicon layer. Thereafter, the first gate insulating layer and the poly silicon layer are patterned to define an island. After that, a gate electrode is formed on the island. Finally, a source region and a drain region are formed inside the poly silicon layer of the island.

According to one embodiment of the present invention, before the gate electrode is formed on the island, the method further comprises a step of forming a second gate insulating layer on the substrate to cover the island.

According to one embodiment of the present invention, after the amorphous silicon layer is melted and re-crystallized to form a poly silicon layer, the method further comprises a step of removing a specific thickness from the first gate insulating layer disposed on the poly silicon layer. After, the poly silicon layer and the first gate insulating layer are patterned. Finally, a second gate insulating layer is formed on the substrate to cover the island.

According to one embodiment of the present invention, the annealing process is a laser annealing process.

According to one embodiment of the present invention, the annealing process is a excimer laser annealing process.

According to one embodiment of the present invention, the laser energy used in the laser annealing process is between 100 mJ/cm² and 100 mJ/cm².

According to one embodiment of the present invention, before the amorphous silicon layer is formed on the substrate, the method further comprises the step of forming a buffer layer on the substrate. The material of the buffer layer comprises silicon dioxide, silicon nitride and a combination thereof.

According to one embodiment of the present invention, after the source region and the drain region are formed, the method further comprises: forming a dielectric layer on the substrate, where the dielectric layer covers the gate electrode, and the dielectric layer and the first gate insulating layer have a plurality of contact holes exposing the source region and the drain region respectively; and forming a source electrode layer and a drain electrode layer on the dielectric layer, where the source electrode layer and the drain electrode layer are electrically connected to the source region and the drain region through the contact holes respectively.

As embodied and broadly described herein, the present invention provides a method of forming a thin film transistor comprising the following steps. First, an amorphous silicon layer is formed on a substrate. Next, an insulating layer is formed on the amorphous silicon layer. Finally, an annealing process is performed such that the amorphous silicon layer is melted and re-crystallized to form a poly silicon layer.

According to one embodiment of the present invention, before the amorphous silicon layer is formed on the substrate, the method further comprises the step of forming a buffer layer on the substrate.

According to one embodiment of the present invention, the material of the buffer layer comprises silicon dioxide, silicon nitride and a combination thereof.

According to one embodiment of the present invention, the annealing process is a laser annealing process.

According to one embodiment of the present invention, the laser annealing process is an excimer laser annealing process.

According to one embodiment of the present invention, the laser energy used in the laser annealing process is between 100 mJ/cm² and 100 mJ/cm².

In the present invention, the amorphous silicon layer and the insulating layer are subsequently formed on the substrate first. Then, the annealing process is performed in order to transform the amorphous silicon layer into the poly silicon layer, and the boundary between the poly silicon layer and the insulating layer would become denser because of the annealing process. Therefore, the current leakage of the thin film transistor would be lower during operation.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A to 1D are schematic, cross-sectional diagrams illustrating a conventional process flow for fabricating a poly silicon thin film transistor.

FIGS. 2A to 2H are schematic, cross-sectional diagrams illustrating a process flow for fabricating a thin film transistor according to the present invention.

FIGS. 3A and 3B are schematic, cross-sectional diagrams showing that a second gate insulating layer is formed on the substrate before the gate electrode is formed.

FIGS. 4A to 4D are schematic, cross-sectional diagrams showing that a specific thickness is removed from the first gate insulating layer and then a second gate insulating layer is formed on the substrate.

FIGS. 5A to 5C are schematic, cross-sectional diagrams illustrating a process flow for fabricating a thin film transistor according to the present invention.

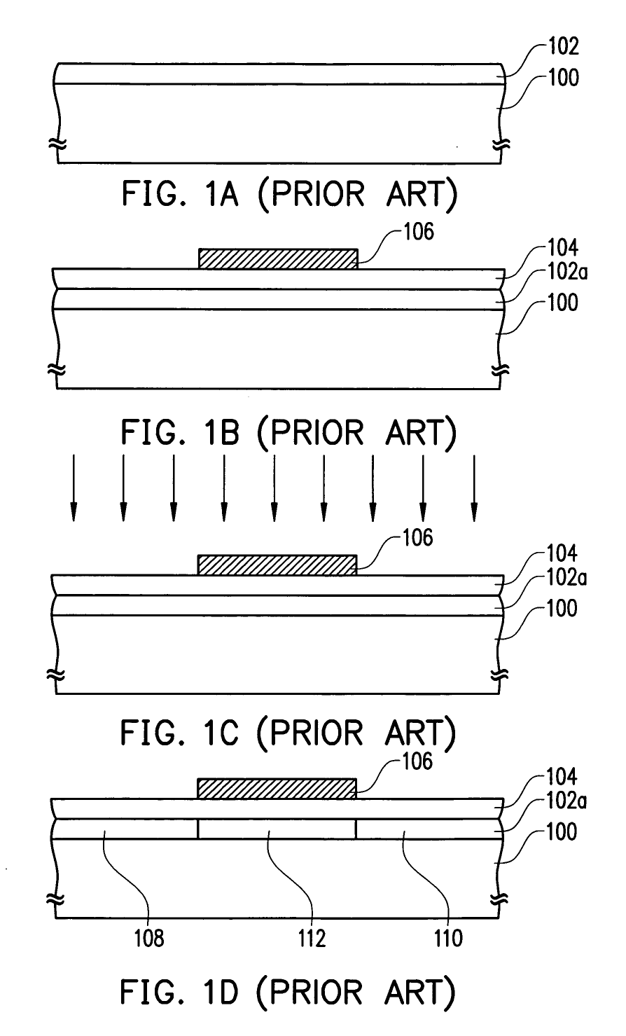

### DESCRIPTION OF THE EMBODIMENTS

Reference will now be made in detail to the present embodiments of the invention, examples of which are illustrated in the accompanying drawings. Wherever possible, the same reference numbers are used in the drawings and the description to refer to the same or like parts.

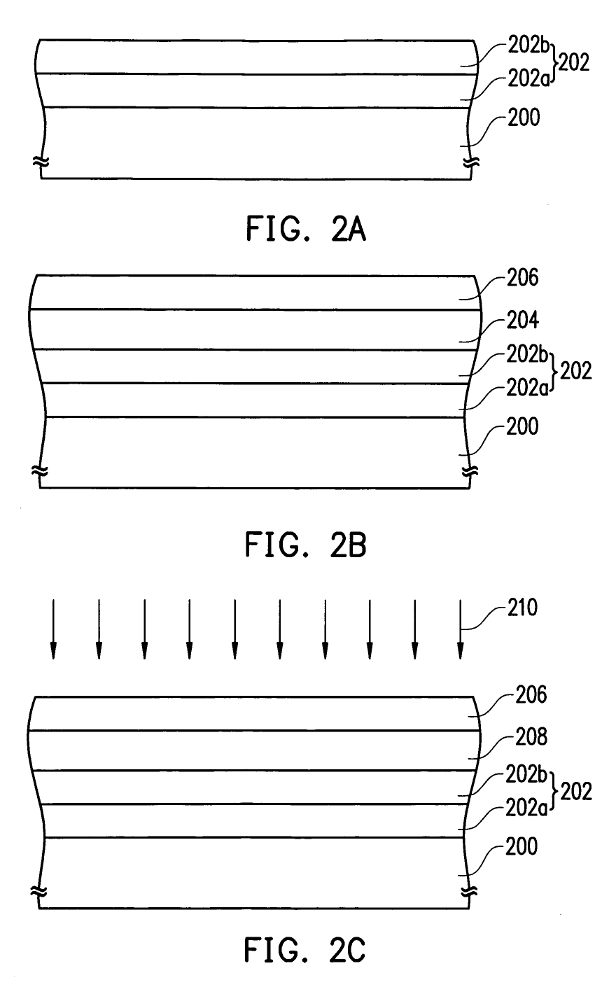

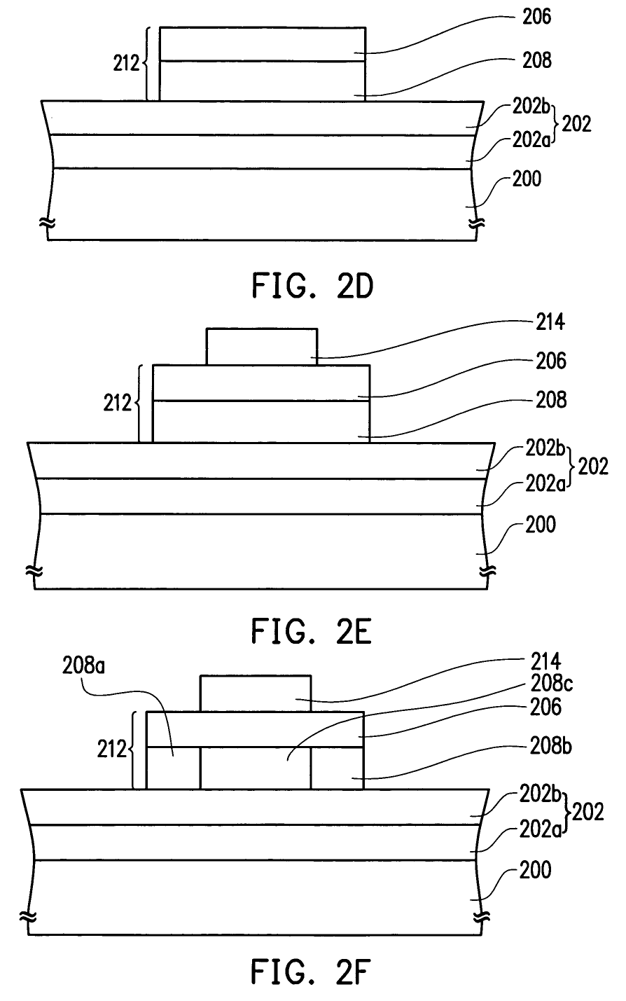

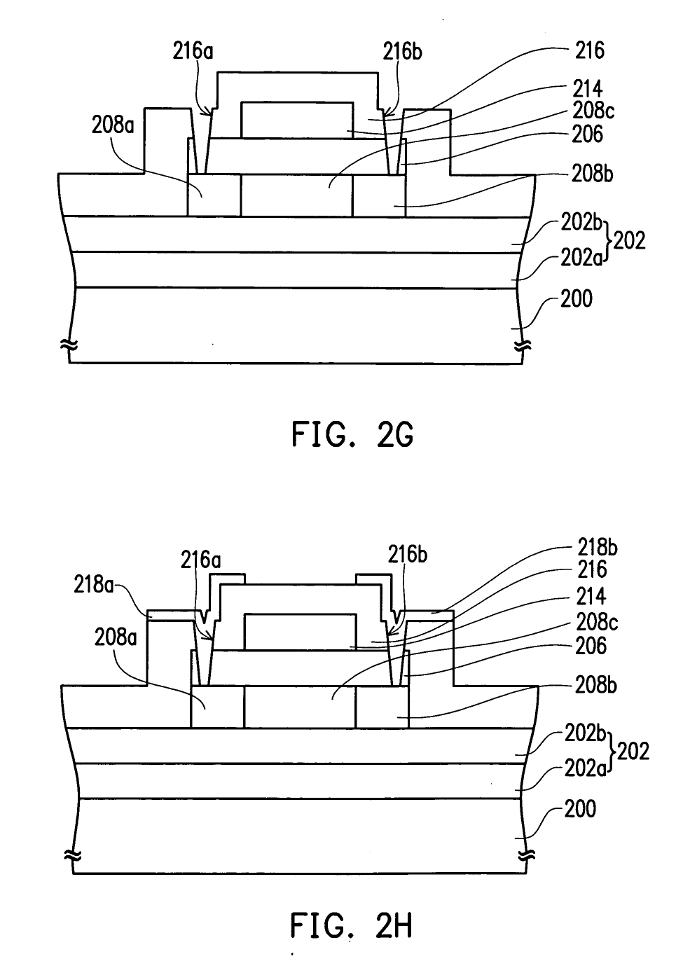

FIGS. 2A to 2H are schematic, cross-sectional diagrams illustrating a process flow for fabricating a thin film transistor according to the present invention. First, please refer to FIG. 2A, a buffer layer 202 is optionally formed on a substrate 200 according to the actual requirement, to avoid the impurities in the substrate 200 from being diffused into the later formed films. In this embodiment, the substrate 200 is a glass substrate, and the buffer layer 202 comprises a silicon nitride layer 202a and a silicon dioxide layer 202b. More specifically, the buffer layer 202 can be a single layer or a multi-layer structure composed of silicon nitride or silicon dioxide. The material and the number of stacked layers of the buffer layer are not limited in the present invention.

Next, please refer to FIG. 2B, an amorphous silicon layer 204 and a first gate insulating layer 206 are formed on the buffer layer 202 subsequently. The material of the first gate insulating layer is silicon dioxide for example. After that, please refer to FIG. 2C, an annealing process is performed such that the amorphous silicon layer 204 shown in FIG. 2B is melted and re-crystallized to form a poly silicon layer 208 shown in FIG. 2C. It should be noted that in the present invention, the annealing process is a laser annealing process, such as the excimer laser beam 210 used in the excimer laser annealing (ELA) process. The laser energy used in the laser annealing process is between 100 mJ/cm² and 100 mJ/cm².

After the annealing process is performed, the boundaries between the buffer layer 202 and the poly silicon layer 208, and between the poly silicon layer 208 and the first gate insulating layer 206 become denser, such that the current leakage of the thin film transistor formed according to the present invention is lower during operation.

Thereafter, please refer to FIG. 2D, the first gate insulating layer 206 and the poly silicon layer 208 are patterned to define an island 212 by the photolithography and etching process. Next, please refer to FIG. 2E, a gate electrode 214 is formed on the island 212. The gate electrode 214 can be formed by the following steps. First, a metal layer (not shown) is formed on the first gate insulating layer, and then the metal layer is patterned by the lithography and etching process to form the gate electrode 214.

After that, please refer to FIG. 2F, a doping process is performed to form a source region 208a and a drain region 208b in the poly silicon layer 208 of the island 212 while a channel region 208c is located between the source region 208a and the drain region 208b. The doping process can use the ion implantation method by taking the gate electrode 214 as a mask, to implant the dopant in the poly silicon layer corresponding in location to the right side and the left side of the gate electrode 214. Besides, a light doping process is optionally performed before forming the source region 208a and the drain region 208b, to form a light doped drain (LDD) (not shown) disposed at one side and the other side of the channel region 208c according to the actual requirement.

The structure shown in FIG. 2F can be called a thin film transistor. Generally speaking, a metal layer electrically connected to the source region 208a and the drain region 208b would be formed, to make the source region 208a and the drain region 208b be electrically connected to other devices through the metal layer. The method for forming the metal layer which is electrically connected to the source region 208a and the drain region 208b is illustrated in the following.

Please refer to FIG. 2G, a dielectric layer 216 is formed on the substrate 200 to cover the gate electrode 214. The dielectric layer 216 and the first gate insulating layer 206 have a plurality of contact holes 216a and 216b to expose the source region 208a and the drain region 208b respectively. Finally, please refer to FIG. 2H, a source metal layer 218a and a drain metal layer 218b are formed on the dielectric layer 216 such that the source metal layer 218a and the drain metal layer 218b are electrically connected to the source region 208a and the drain region 208b through the contact holes 216a and 216b respectively. Thus far, the thin film transistor is formed according to the above processes.

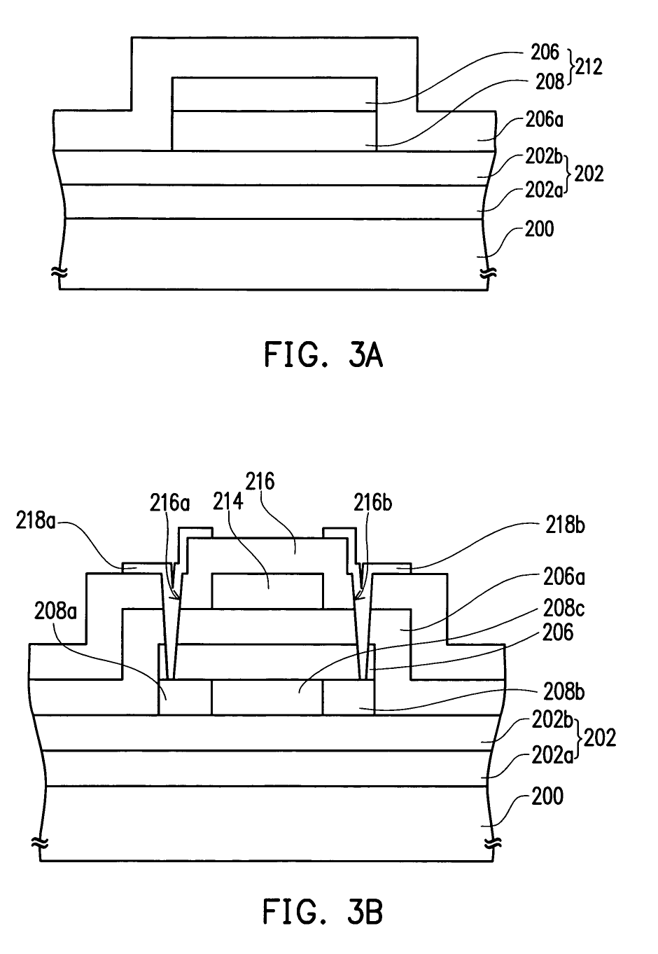

In the other embodiment of the present invention, the buffer layer 202 and the island 212 can be subsequently formed on the substrate 200 as shown in FIG. 2A to FIG. 2D. After that, please refer to FIG. 3A, a second gate insulating layer 206a is formed on the buffer layer 202 to cover the island 212. Next, the gate electrode 214, the dielectric layer 216, the contact holes 216a and 216b, the source metal layer 218a and the drain metal layer 218b are subsequently formed on the second gate insulating layer 206a by using the steps shown in FIG. 2E to FIG. 2H, to form a thin film transistor as shown in FIG. 3B. Because the second gate insulting layer 206a is additionally formed on the buffer layer 202 to cover the island 212, such that the insulation effect between the poly silicon layer 208 and the gate electrode 214 can be enhanced, to make sure that the poly silicon layer 208 is not electrically connected to the gate electrode 214.

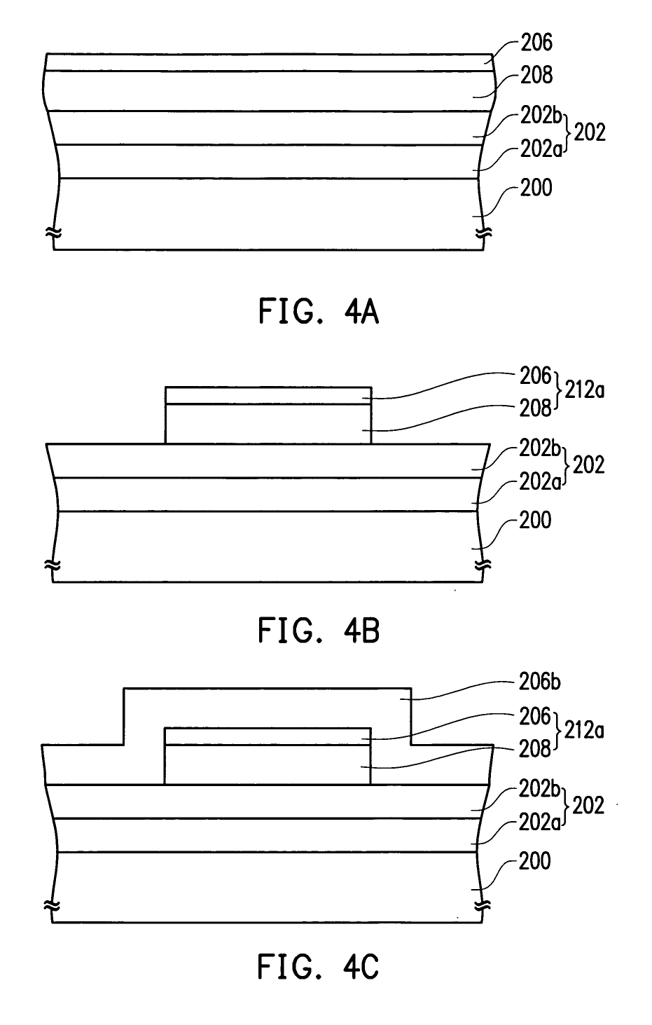

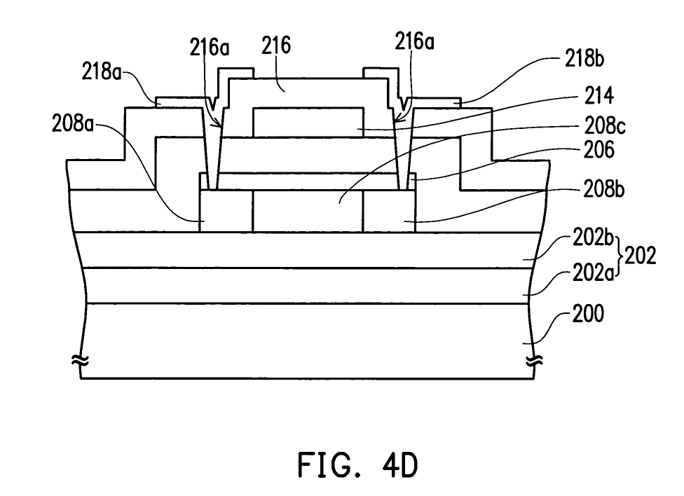

Besides, during the annealing process, the laser beam passes through the first gate insulating layer 206 first and then arrives the amorphous silicon layer 204, such that the lattice of the first gate insulating layer 206 may be damaged by the laser beam. Therefore, in another embodiment of the present invention, the buffer layer 202, the poly silicon layer 208 and the first gate insulating layer 206 are subsequently formed on the first gate insulating layer 206 by using the steps shown in FIG. 2A to FIG. 2C. Next, please refer to FIG. 4A, a specific thickness is removed from the first gate insulating layer 206 disposed on the poly silicon layer 208. Thereafter, the first gate insulating layer 206 and the poly silicon layer 208 are patterned to define an island 212a. After that, a second gate insulating layer 206b is formed on the substrate 200 to cover the island 212a. Because the laser beam does not pass through the second gate insulating layer 206b, therefore, the insulation effect between the poly silicon layer 208 and the gate electrode 214 can be enhanced. Thereafter, the gate electrode 214, the dielectric layer 216, the contact holes 216a and 216b, the source metal layer 218a and the drain metal layer 218b are subsequently formed on the second gate insulating layer 206a by using the steps shown in FIG. 2E to FIG. 2H, to form a thin film transistor as shown in FIG. 4D.

The present invention also provides a method of forming a poly silicon layer of a LTPS thin film transistor, which can be applied to the fabrication process of a top gate LTPS thin film transistor. Similarly, the amorphous silicon layer and the insulating layer are subsequently deposited on a substrate. After that, the annealing process is performed, such that the amorphous silicon layer is transformed into a poly silicon layer. At this time, the boundary between the poly silicon layer and the gate insulating layer would become denser because of the annealing process. Therefore, the current leakage of the thin film transistor formed by the above-mentioned fabrication process can be improved during operation.

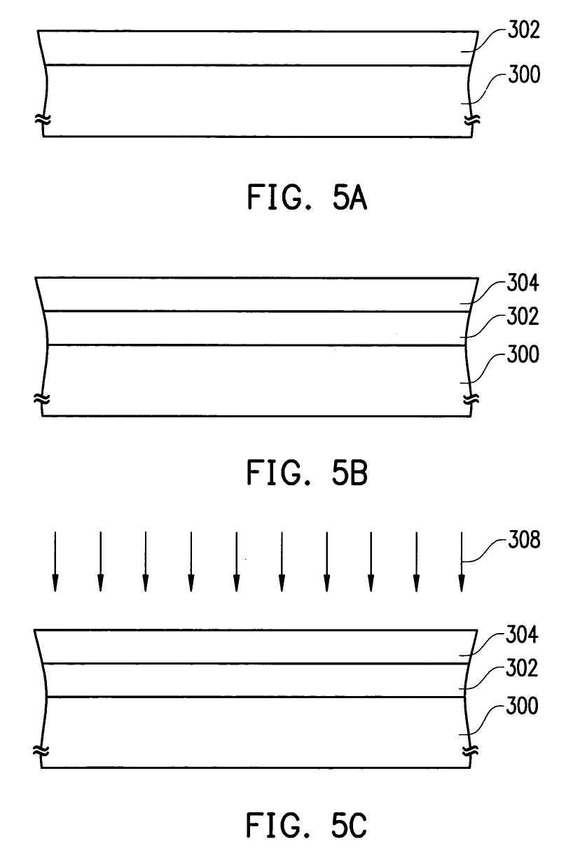

FIGS. 5A to 5C are schematic, cross-sectional diagrams illustrating a process flow for fabricating a thin film transistor according to the present invention. First, please refer to FIG. 5A, an amorphous silicon layer 302 is formed on a substrate 300. Similarly, a buffer layer (not shown) is optionally formed on the substrate 300 to avoid the impurities inside the substrate 300 from being diffused into the later formed films.

Next, please refer to FIG. 5B, an insulating layer 304, which can be taken as the gate insulating layer of the thin film transistor, is formed on the amorphous silicon layer 302. After that, please refer to FIG. 5C, an annealing process is performed to make the amorphous silicon layer 302 be melted and re-crystallized to form a poly silicon layer 306. It should be noted that in the present invention, the annealing process is a laser annealing process, such as the excimer laser beam 210 used in the excimer laser annealing (ELA) process. The laser energy used in the laser annealing process is between 100 mJ/cm² and 100 mJ/cm².

In summary, the amorphous silicon layer and the insulating layer are subsequently formed on the substrate first. Then, the annealing process is performed in order to transform the amorphous silicon layer into the poly silicon layer, and the boundary between the poly silicon layer and the insulating layer would become denser because of the annealing process. Therefore, the current leakage of the thin film transistor would be lower during operation.

It will be apparent to those skilled in the art that various modifications and variations may be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of forming a thin film transistor, comprising:
forming an amorphous silicon layer on a substrate;
forming a first gate insulating layer on the amorphous silicon layer;
performing an annealing process such that the amorphous silicon layer is melted and re-crystallized to form a poly silicon layer;
patterning the first gate insulating layer and the poly silicon layer to define an island;
forming a gate electrode on the island; and
forming a source region and a drain region inside the poly silicon layer of the island.

2. The method of forming a thin film transistor according to claim 1, wherein before the gate electrode is formed on the island, the method further comprises a step of forming a second gate insulating layer on the substrate to cover the island.

3. The method of forming a thin film transistor according to claim 1, wherein after the amorphous silicon layer is melted and re-crystallized to form a poly silicon layer, the method further comprises a step of removing a specific thickness from the first gate insulating layer disposed on the poly silicon layer.

4. The method of forming a thin film transistor according to claim 3, wherein after the specific thickness is removed from the first gate insulating layer, the method further comprises a step of forming a second gate insulating layer on the substrate to cover the island.

5. The method of forming a thin film transistor according to claim 1, wherein the annealing process is a laser annealing process.

6. The method of forming a thin film transistor according to claim 5, wherein the laser annealing process is an excimer laser annealing process.

7. The method of forming a thin film transistor according to claim 5, wherein the laser energy used in the laser annealing process is between 100 mJ/cm² and 100 mJ/cm².

8. The method of forming a thin film transistor according to claim 1, wherein before the amorphous silicon layer is formed on the substrate, the method further comprises the step of forming a buffer layer on the substrate.

9. The method of forming a thin film transistor according to claim 8, wherein a material of the buffer layer comprises silicon dioxide, silicon nitride and a combination thereof.

10. The method of forming a thin film transistor according to claim 1, wherein after the source region and the drain region are formed, the method further comprises:
forming a dielectric layer on the substrate, wherein the dielectric layer covers the gate electrode, and the dielectric layer and the first gate insulating layer have a plurality of contact holes exposing the source region and the drain region respectively; and
forming a source electrode layer and a drain electrode layer on the dielectric layer, wherein the source electrode layer and the drain electrode layer are electrically connected to the source region and the drain region through the contact holes respectively.

11. A method of forming a poly silicon layer of a low temperature poly silicon thin film transistor, comprising:
forming an amorphous silicon layer on a substrate;
forming an insulating layer on the amorphous silicon layer; and
performing an annealing process such that the amorphous silicon layer is melted and re-crystallized to form a poly silicon layer.

12. The method of forming a poly silicon layer of a low temperature poly silicon thin film transistor according to claim 11, wherein before the amorphous silicon layer is formed on the substrate, the method further comprises the step of forming a buffer layer on the substrate.

13. The method of forming a poly silicon layer of a low temperature poly silicon thin film transistor according to claim 12, wherein a material of the buffer layer comprises silicon dioxide, silicon nitride and a combination thereof.

14. The method of forming a poly silicon layer of a low temperature poly silicon thin film transistor according to claim 11, wherein the annealing process is a laser annealing process.

15. The method of forming a thin film transistor according to claim 14, wherein the laser annealing process is an excimer laser annealing process.

16. The method of forming a thin film transistor according to claim 14, wherein the laser energy used in the laser annealing process is between 100 mJ/cm² and 100 mJ/cm².
